(19) United States
(12) Patent Application Publication
(10) Pub. No.: US 2006/0234399 A1
(43) Pub. Date: Oct. 19, 2006

(54) Meander metal line under the pad for improved device MM ESD performance

(75) Inventors: Jiaw-Ren Shih, Hsin-Chu (TW); Jian-Hsing Lee, Hsin-Chu (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/107,068

(22) Filed: Apr. 15, 2005

(51) Int. Cl. H01L 21/00

(52) U.S. Cl. 438/10

(57) ABSTRACT

A method is disclosed for enhancing ESD protection of integrated circuit devices. The method entails placing a resistor between an I/O pad and an ESD protection device on a semiconductor chip so that one end of the resistor connects to pins on said I/O pad and the other end connects to the ESD protection device.

### BACKGROUND OF THE INVENTION

(1) Field of the Invention

The present invention relates generally to protection of semiconductor integrated circuits from damage by static electricity. More particularly, this invention relates to techniques for improving the ability of semiconductor integrated circuits to withstand electrostatic discharge (ESD).

(2) Description of Prior Art

As is well known in the art, static electric discharge can cause extensive damage to electronic components. Since loses due to ESD can be substantial much effort has been expended to prevent such discharges and also to protect electronic components by utilizing ESD protection devices. Tests are performed to evaluate the extent of protection provided semiconductor integrated circuits from ESD in various environments. The machine model (MM) test evaluates the immunity of semiconductor integrated circuits from machine to circuits. Results of the MM test can be presented in terms of a device MM passing voltage. Higher values of MM passing voltage indicate more robust protection. The generally accepted current industrial specification for device MM passing voltage is 200 volts. With the trend toward smaller devices and smaller current paths the susceptibility for damage due to ESD is increased and greater protection is required. Furthermore, increased protection is always desirable if it could be provided efficiently and economically.

Ker et al., U.S. Pat. No. 5,473,169, disclose a complementary silicon controlled rectifier ESD protection circuit that, when adjacent well spacing is made small, provides increased MM passing voltage. In the present invention increased MM passing voltage is achieved without altering the ESD protection device.

### SUMMARY OF THE INVENTION

It is a primary objective of the invention to provide a method for increasing device MM passing voltage. It is a further primary objective of the invention to provide a method for increasing device MM passing voltage without alteration of the ESD protection device. It is yet a further primary objective of the invention to provide a method for increasing device MM passing voltage without utilizing chip device area.

These objectives are attained in the invention by forming long conductive lines in series with ESD protection devices and so situated that chip device area is not utilized. Meandering conductive lines are appropriate structures to attain long conductive lines. The resistance of the long conductive line determines the increase in device MM passing voltage, with a larger increase in MM passing voltage for a more resistive line. Device MM passing voltages more than doubling the current industrial specification are readily achievable. It is efficient to place the long conductive line under the I/O pad between the pad and device conductive lines so that no device area is expended for the conductive long lines.

### BRIEF DESCRIPTION OF THE DRAWINGS

In the accompanying drawing forming a material part of this description, there is shown:

FIG. 1 shows a top view of a meandering conductive line connecting a pad to an ESD protection device to improve MM passing voltage.

FIG. 2 shows a cross-sectional view of a meandering conductive line connecting a pad to an ESD protection device to improve MM passing voltage.

### DESCRIPTION OF THE PREFERRED EMBODIMENTS

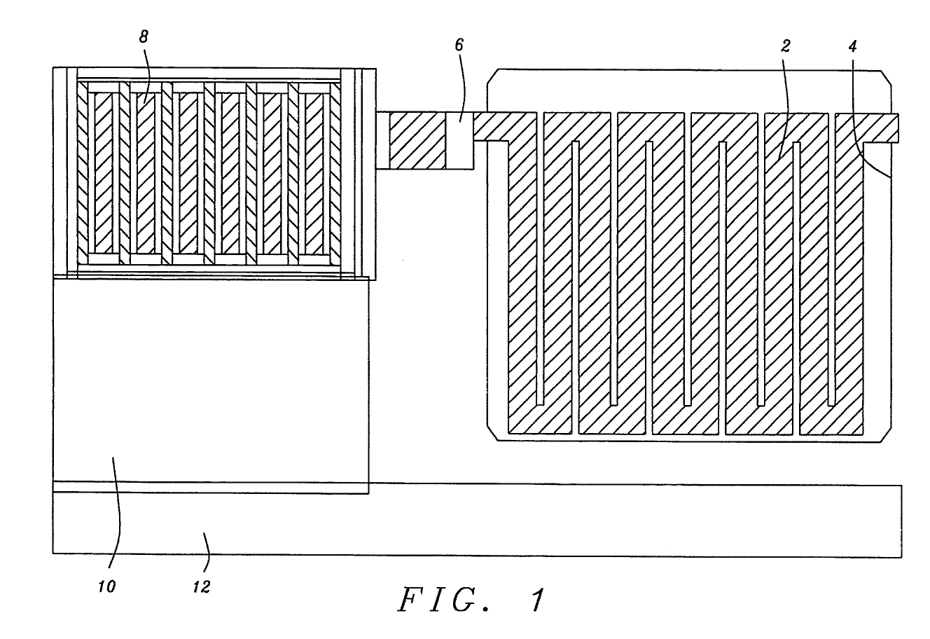

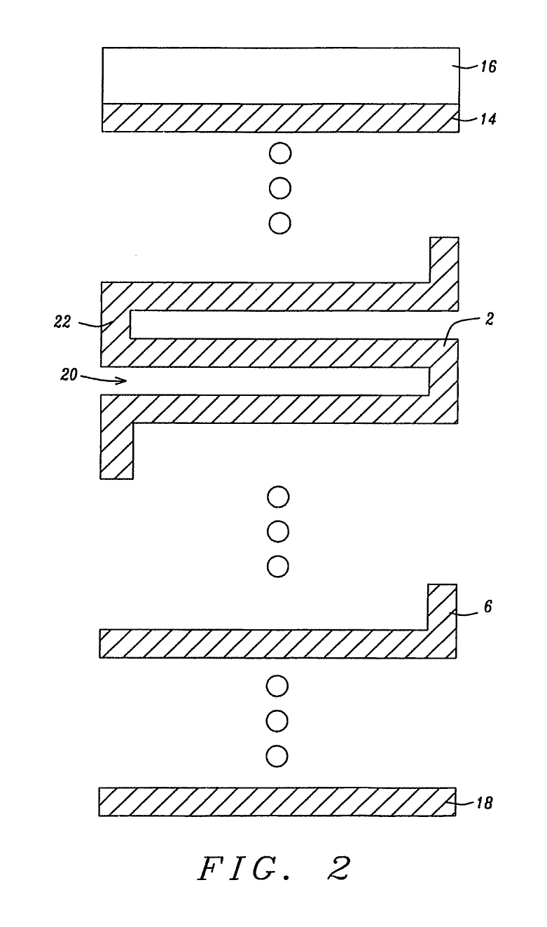

Preferred embodiments of the invention are well described with the aid of FIGS. 1 and 2 in which are shown meandering conductive line configurations according to preferred embodiments of the invention. FIG. 1 shows a top view and FIG. 2 shows a cross-sectional view of a meandering conductive line connecting a pad to an ESD protection device to improve MM passing voltage. Shown in FIGS. 1 and 2 are meandering conductive lines, 2 that are disposed under an I/O pad, 16, whose outline 4 is indicated in FIG. 1. One end of the meandering conductive lines connects to pins on the pad (not shown) and the other end connects to conductive lines, 6 that lead to and connect with an ESD protective device 8 that is situated in a device portion, 10, of a silicon substrate. Also shown in FIG. 1 is the bus line 12 for connection to ground. As is seen in FIG. 2 the meander lines, 2 can occupy a multiplicity of levels; three are shown for purpose of illustration. Dielectric layers 20 separate meander line levels and the lines at adjoining levels are connected by via structures 22. The meander lines can be disposed under a top metal layer, 14 that is situated under the pad, 16, and under other layers as may be required. As is usual, there is a multiplicity of conductive layers 18, of FIG. 2, which connect device to pad.

Although it is efficient to place the meander line under the pad, as described above, any available area would do. It is required that one end of the line connects to pins on the pad and the other end connects to lines leading to the protective device and the line resistance needs to be large enough, then an increase in the MM passing voltage is obtained.

The MM passing voltage measured when meander lines of various widths and lengths are used is given in Table 1. Here, the entries of the first row, which is labeled (L/W), provide the length, L, and width, W, of a meander line in micrometers. Thus the entry “5/30” of the first column of the first row indicates that the length of the meander line is 5 micrometers and its width is 30 micrometers. An entry of the second row provides the measured MM passing voltage, in volts, when using a meander line having length and width values given in the same column of the first row.

TABLE 1

| | | | |
|---|---|---|---|
| (L/W) | 5/30 | 1500/10 | 3000/5 |
| MM | 200 | 300 | 450 |

For the short, wide meander line of the first column there is no perceptible increase in the MM passing voltage, which is about 200 volts when no meander line is used. The resistance of the meander line of the second column is 900 times that of the first column and the MM passing voltage is increased by 50% to 300 volts. Meander lines of the third column have a resistance that is four times that of second column lines and MM voltages of 450 volts, 50% higher than for the second column lines and 225% larger than the 200 volt MM passing voltage when no meander line is used, and which is the current industrial specification. It is apparent that long meander lines in series with ESD protection devices can significantly increase the MM passing voltage. Thus substantial improvement in ESD protection results just by interposing a long meander line between the pad and the ESD protection device. Notably this improvement is achieved without any alteration of the ESD protection device and with no cost in device real estate. Preferably the long meander line is situated under the I/O pad. Then essentially the only alteration required being the introduction of additional metal levels to accommodate the meander line.

The governing property of the interposed line, giving rise to the increased MM passing voltage, is its resistance. Any element having the same resistance that is interposed between the pad and ESD protection device will have the same effect. Thus thin film deposited resistors, such as nichrome, tantalum or cermet thin film resistors will essentially act the same as long polysilicon lines of the same resistance. Also most any conductive material could be used for the meander lines. Thus polysilicon, metals metal silicides and composites of these and other materials are appropriate for the meander lines. It is only necessary that a resistor with resistance efficiently large to achieve the desired increase in the MM passing voltage be inserted in series with the ESD protection device, with one end of the resistor connected to pins on the pad and the other end connected to the ESD protection device.

Techniques for forming conductive lines and thin film resistors are well known in detail by those versed in the art. These techniques include forming, etching and patterning dielectric and conductive layers.

While the invention has been particularly shown and described with reference to the preferred embodiments thereof, it will be understood by those skilled in the art that various changes in form and detail may be made without departing from the spirit and scope of the invention.

What is claimed is:

1. A method for enhancing ESD protection of integrated circuit devices comprising:
placing a resistor between an I/O pad and an ESD protection device on a semiconductor chip so that an end of the resistor connects to pins on said I/O pad and an other end connects to said ESD protection device.

2. The method of claim 1 wherein resistance of said resistor is adjusted to achieve a value of MM passing voltage, a measure of ESD protection, by increasing said resistance to achieve increased MM passing voltage.

3. The method of claim 1 wherein said resistor is a polysilicon line.

4. The method of claim 1 wherein said resistor is a metal line.

5. The method of claim 1 wherein said resistor is a metal silicide line.

6. The method of claim 1 wherein said resistor is a nichrome thin film resistor.

7. The method of claim 1 wherein said resistor is a tantalum thin film resistor.

8. The method of claim 1 wherein said resistor is a cermet thin film resistor.

9. The method of claim 1 wherein said resistor is composed of a composite of metals and other materials.

10. A method for enhancing ESD protection of integrated circuit devices comprising:
providing a partially processed semiconductor chip having product devices and ESD protection device and, under an I/O pad area, product device metal levels and ESD protection device metal levels;
forming a multiplicity of layers containing a resistor whose lower end connects to said ESD protection device metal levels and whose upper end connects to pins of an I/O pad;
forming top metal levels and said I/O pad above said top metal levels.

11. The method of claim 10 wherein said semiconductor chip is a silicon chip.

12. The method of claim 10 wherein resistance of said resistor is adjusted to achieve a value of MM passing voltage, a measure of ESD protection, by increasing said resistance to achieve increased MM passing voltage.

13. The method of claim 10 wherein said resistor is a polysilicon line.

14. The method of claim 10 wherein said resistor is a metal line.

15. The method of claim 10 wherein said resistor is a metal silicide line.

16. The method of claim 10 wherein said resistor is a nichrome thin film resistor.

17. The method of claim 10 wherein said resistor is a tantalum thin film resistor.

18. The method of claim 10 wherein said resistor is cermet thin film resistor.

19. The method of claim 10 wherein said resistor is a composite of metals and other materials.

20. A method for enhancing ESD protection of integrated circuit devices comprising:
providing a partially processed semiconductor chip having product devices and ESD protection device and, under an I/O pad area, product device metal levels and ESD protection device metal levels;
forming a multiplicity of meander levels of meandering conductive lines separated from each other and from metal levels below and above by dielectric layers, with the lowest said meander level line connected to said ESD protection device metal levels, with said meandering conductive lines of said multiplicity of said meander levels connected in series to form a meander line series and with the line of the top meander level connected to top metal levels that lead to pins of an I/O pad, all connections being through the intervening dielectric levels;
forming said top metal levels and said I/O pad disposed over said top metal levels.

21. The method of claim 20 wherein said semiconductor chip is a silicon chip.

22. The method of claim 10 wherein resistance of said meander line series is adjusted to achieve a value of MM passing voltage, a measure of ESD protection, by increasing said resistance to achieve increased MM passing voltage.

23. The method of claim 10 wherein said meander conductive lines are polysilicon lines.

24. The method of claim 10 wherein said meander conductive lines are metal lines.

25. The method of claim 10 wherein said meander conductive lines are metal silicide lines.

26. The method of claim 10 wherein said meander conductive lines are composites of metals and other materials.

27. The method of claim 20 wherein said dielectric layers are composed of oxide, nitride or oxynitride or combinations of these materials.
